(19) United States
(12) Patent Application Publication
(10) Pub. No.: US 2024/0324211 A1
(43) Pub. Date: Sep. 26, 2024

(54) SEMICONDUCTOR STORAGE DEVICE

(71) Applicant: Kioxia Corporation, Tokyo (JP)

(72) Inventor: Yuto ARINAGA, Yokkaichi Mie (JP)

(73) Assignee: Kioxia Corporation, Tokyo (JP)

(21) Appl. No.: 18/592,089

(22) Filed: Feb. 29, 2024

(30) Foreign Application Priority Data
Mar. 22, 2023 (JP) 2023-044969

(51) Int. Cl. H10B 43/27

(52) U.S. Cl. CPC H10B 43/27

(57) ABSTRACT

A semiconductor storage device includes a multiple multilayer films multiple insulating films that each penetrate the multilayer films, multiple memory pillars provided between the insulating films and that respective penetrate a multilayer film, multiple columnar portions with respective cross-sectional areas larger than that of respective memory pillars at certain surfaces.

### CROSS-REFERENCE TO RELATED APPLICATION

This application is based upon and claims the benefit of priority from Japanese Patent Application No. 2023-044969, filed Mar. 22, 2023, the entire contents of which are incorporated herein by reference.

### FIELD

Embodiments described herein relate generally to a semiconductor storage device.

### BACKGROUND

A large-capacity semiconductor storage device has been developed. This large-capacity semiconductor storage device is able to perform low-voltage and low-current operation, high-speed switching, and miniaturization and high integration of memory cells.

In a memory cell array provided in the semiconductor storage device, a large number of metal wirings called bit lines and word lines are arranged. A voltage is applied to the bit line and the word line connected to the cell, and data is written into one memory cell corresponding to the bit line and the word line. The semiconductor storage device includes a stacked body in which a conductive layer and an insulating layer serving as the word line are alternately stacked. The semiconductor storage device includes memory cells arranged in three dimensions.

### DESCRIPTION OF THE DRAWINGS

FIG. 1 is an example of a configuration of a semiconductor storage device according to at least one embodiment.

FIG. 2 is an example of a circuit configuration of a memory cell array according to at least one embodiment.

FIG. 3 is a schematic sectional view showing an example of the memory cell array in at least one embodiment.

FIG. 4 is a schematic top view of the memory cell array of at least one embodiment.

FIG. 5 is a schematic sectional view of a columnar portion HR1.

FIG. 6 is a schematic sectional view of a columnar portion HR2.

FIG. 7 is a schematic sectional view showing a manufacturing step of the semiconductor storage device of at least one embodiment.

FIG. 8 is a schematic sectional view showing a manufacturing step of the semiconductor storage device of at least one embodiment.

FIG. 9 is a schematic sectional view showing a manufacturing step of the semiconductor storage device of at least one embodiment.

FIG. 10 is a schematic sectional view showing a manufacturing step of the semiconductor storage device of at least one embodiment.

FIG. 11 is a schematic sectional view showing a manufacturing step of the semiconductor storage device of at least one embodiment.

FIG. 12 is a schematic sectional view showing a manufacturing step of the semiconductor storage device of at least one embodiment.

FIG. 13 is a schematic sectional view showing a manufacturing step of the semiconductor storage device of at least one embodiment.

FIG. 14 is a schematic sectional view showing a manufacturing step of the semiconductor storage device of at least one embodiment.

FIG. 15 is a schematic sectional view showing a manufacturing step of the semiconductor storage device of at least one embodiment.

FIG. 16 is a schematic sectional view showing a manufacturing step of the semiconductor storage device of at least one embodiment.

FIG. 17 is a schematic sectional view showing a manufacturing step of the semiconductor storage device of at least one embodiment.

FIG. 18 is a schematic sectional view showing a manufacturing step of the semiconductor storage device of at least one embodiment.

### DETAILED DESCRIPTION

At least one embodiment provides a semiconductor storage device that is easily manufactured.

In general, according to at least one embodiment, a semiconductor storage device of the embodiment includes a first stacked body in which a plurality of first conductive layers and a plurality of first insulating layers are alternately stacked one by one in a first direction, and that extends in a second direction intersecting the first direction and a third direction intersecting the first direction and the second direction; a second stacked body that is provided along with the first stacked body in the first direction, in which plurality of second conductive layers and a plurality of second insulating layers are alternately stacked one by one in the first direction, and that extends in the second direction and the third direction; a first insulating film that penetrates the first stacked body and the second stacked body in the first direction and extends in the second direction; a second insulating film that is provided apart from the first insulating film in the third direction, penetrates the first stacked body and the second stacked body in the first direction, and extends in the second direction; a plurality of first memory pillars that are provided between the first insulating film and the second insulating film, and each of which penetrates the first stacked body in the first direction, and has a plurality of first memory cells; a plurality of second memory pillars that are provided between the first insulating film and the second insulating film, and each of which penetrates the second stacked body in the first direction, has a plurality of second memory cells, and is connected to the first memory pillars in the first direction; a plurality of first columnar portions, each of which penetrates the first stacked body in the first direction in between the first insulating film and the second insulating film, is provided apart from the plurality of first memory pillars in the second direction, and has a cross-sectional area larger than a cross-sectional area of the first memory pillar in a first surface parallel to the second direction and the third direction; a plurality of second columnar portions, each of which penetrates the second stacked body in the first direction in between the first insulating film and the second insulating film, is provided apart from the plurality of second memory pillars in the second direction, has a cross-sectional area larger than a cross-sectional area of the second memory pillar in a second surface parallel to the second direction and the third direction, and is connected to the plurality of first columnar portions in the first direction; a plurality of third columnar portions, each of which penetrates the first stacked body in the first direction in between the first memory pillar and the first columnar portion, is apart from the first memory pillars, is provided in contact with the first columnar portion in the second direction, and has a cross-sectional area larger than the cross-sectional area of the first memory pillar in the first surface; and a plurality of fourth columnar portions, each of which penetrates the second stacked body in the first direction in between the second memory pillar and the second columnar portion, is apart from the second memory pillar, is provided in contact with the second columnar portion in the second direction, has a cross-sectional area larger than the cross-sectional area of the second memory pillar in second surface, and is connected to the plurality of third columnar portions in the first direction.

Hereinafter, an embodiment will be described with reference to the accompanying drawings. In the drawings, the same or similar parts are denoted by the same or similar reference numerals.

In the present specification, in order to indicate a positional relationship of components and the like, an upper direction of a drawing is described as “upper”, and a lower direction of the drawing is described as “lower”. In the present specification, the concepts of “upper” and “lower” are not necessarily terms indicating a relationship with the direction of gravity.

### Embodiment

A semiconductor storage device of an embodiment includes a first stacked body in which a plurality of first conductive layers and a plurality of first insulating layers are alternately stacked one by one in a first direction, and that extends in a second direction intersecting the first direction and a third direction intersecting the first direction and the second direction; a second stacked body that is provided along with the first stacked body in the first direction, in which a plurality of second conductive layers and a plurality of second insulating layers are alternately stacked one by one in the first direction, and that extends in the second direction and the third direction; a first insulating film that penetrates the first stacked body and the second stacked body in the first direction and extends in the second direction; a second insulating film that is provided apart from the first insulating film in the third direction, penetrates the first stacked body and the second stacked body in the first direction, and extends in the second direction; a plurality of first memory pillars that are provided between the first insulating film and the second insulating film, and each of which penetrates the first stacked body in the first direction, and has a plurality of first memory cells; a plurality of second memory pillars that are provided between the first insulating film and the second insulating film, and each of which penetrates the second stacked body in the first direction, has a plurality of second memory cells, and is connected to the first memory pillars in the first direction; a plurality of first columnar portions, each of which penetrates the first stacked body in the first direction in between the first insulating film and the second insulating film, is provided apart from the plurality of first memory pillars in the second direction, and has a cross-sectional area larger than a cross-sectional area of the first memory pillar in a first surface parallel to the second direction and the third direction; a plurality of second columnar portions, each of which penetrates the second stacked body in the first direction in between the first insulating film and the second insulating film, is provided apart from the plurality of second memory pillars in the second direction, has a cross-sectional area larger than a cross-sectional area of the second memory pillar in a second surface parallel to the second direction and the third direction, and is connected to the plurality of first columnar portions in the first direction; a plurality of third columnar portions, each of which penetrates the first stacked body in the first direction in between the first memory pillar and the first columnar portion, is apart from the first memory pillars, is provided in contact with the first columnar portion in the second direction, and has a cross-sectional area larger than the cross-sectional area of the first memory pillar in the first surface; and a plurality of fourth columnar portions, each of which penetrates the second stacked body in the first direction in between the second memory pillar and the second columnar portion, is apart from the second memory pillar, is provided in contact with the second columnar portion in the second direction, has a cross-sectional area larger than the cross-sectional 1 area of the second memory pillar in second surface, and is connected to the plurality of third columnar portions in the first direction.

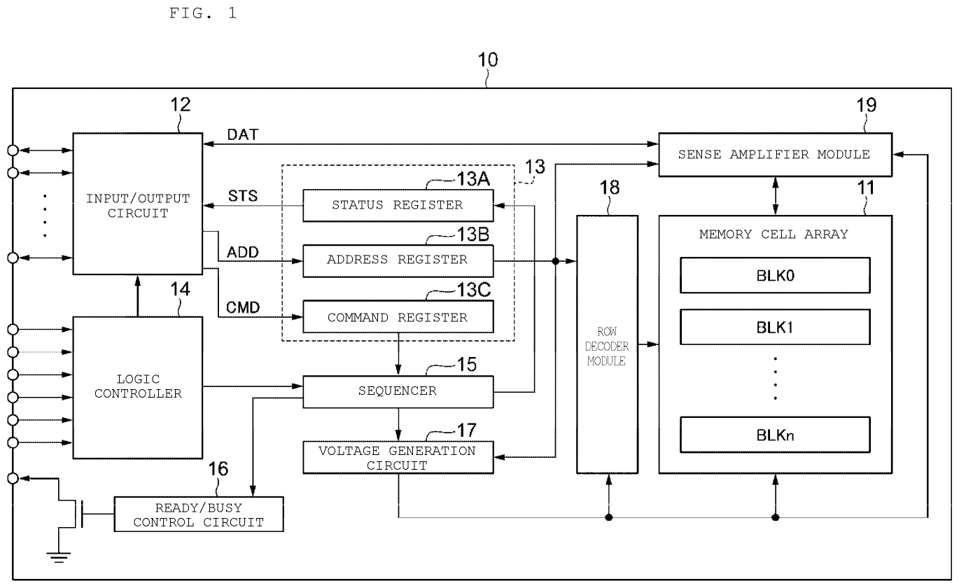

FIG. 1 shows an example of a configuration of a semiconductor storage device 10 according to an embodiment. As shown in FIG. 1, the semiconductor storage device 10 includes a memory cell array 11, an input/output circuit 12, a register unit 13, a logic controller 14, a sequencer 15, a ready/busy control circuit 16, a voltage generation circuit 17, a row decoder module 18, and a sense amplifier module 19.

The memory cell array 11 includes blocks BLK0 to BLKn (n is an integer equal to or larger than 1). The block BLK is a set of a plurality of nonvolatile memory cells associated with a bit line and a word line, and is, for example, a data erasure unit. The present disclosure is not limited to this, and other erasing operations are described in U.S. patent application Ser. No. 13/235,389 filed on Sep. 18, 2011, entitled “Nonvolatile Semiconductor Storage Device” and U.S. patent application Ser. No. 12/694,690 filed on Jan. 27, 2010, entitled “Nonvolatile Semiconductor Storage Device”. The entire contents of these patent applications are incorporated herein by reference.

8-bit wide input/output signals I/O1 to I/O8 are communicated between the external memory controller and the input/output circuit 12 by the input/output circuit 12, for example. The input/output signal I/O includes, for example, data DAT, address information ADD, a command CMD, or the like. For example, the input/output circuit 12 transfers the data DAT received from the external memory controller to the sense amplifier module 19. The input/output circuit 12 transmits the data DAT read from the memory cell array 11 by the sense amplifier module 19 and transferred from the sense amplifier module 19 to the external memory controller.

The register unit 13 includes a status register 13A, an address register 13B, and a command register 13C. The status register 13A stores, for example, the status information STS of the sequencer 15, and transfers the status information STS to the input/output circuit 12 based on an instruction of the sequencer 15. The address register 13B stores the address information ADD transferred from the input/output circuit 12. The address information ADD includes, for example, a block address, a page address, and a column address. The command register 13C stores a command CMD transferred from the input/output circuit 12.

The logic controller 14 controls each of the input/output circuit 12 and the sequencer 15 based on various control signals received from the external memory controller. The various control signals, for example, a chip enable signal/CE, a command latch enable signal CLE, an address latch enable signal ALE, a write enable signal/WE, a read enable signal/RE, and a write protect signal/WP are used. The chip enable signal/CE is a signal for enabling the semiconductor storage device 10. The command latch enable signal CLE is a signal for notifying the input/output circuit 12 that the received input/output signal I/O is a command CMD. The address latch enable signal ALE is a signal for notifying the input/output circuit 12 that the received input/output signal I/O is the address information ADD. The write enable signal/WE is a signal for instructing the input/output circuit 12 to input the input/output signal I/O. The read enable signal/RE is a signal for instructing the input/output circuit 12 to output the input/output signal I/O. The write protect signal/WP is a signal for putting the semiconductor storage device 10 in a protected state when the power is turned on and off.

The sequencer 15 controls the operation of the entire semiconductor storage device 10 based on the address information ADD and the command CMD stored in the register unit 13. For example, the sequencer 15 controls the voltage generation circuit 17, the row decoder module 18, the sense amplifier module 19, and the like to execute a write/read operation.

The ready/busy control circuit 16 generates a ready/busy signal RBn based on the operation state of the sequencer 15. The ready/busy signal RBn is a signal for notifying the external controller of whether the semiconductor storage device 10 is in a ready state in which the semiconductor storage device 10 receives a command from the external memory controller or is in a busy state in which the semiconductor storage device 10 does not receive the command.

The voltage generation circuit 17 generates a desired voltage based on the control of the sequencer 15, and supplies the generated voltage to the memory cell array 11, the row decoder module 18, the sense amplifier module 19, and the like. For example, the voltage generation circuit 17 applies the desired voltage to the word line selected based on the page address stored in the address register 13B.

The row decoder module 18 selects the block BLK that executes various operations based on the block address stored in the address register 13B. The row decoder module 18 applies the voltage supplied from the voltage generation circuit 17 to, for example, the word line provided in the selected block BLK.

The sense amplifier module 19 reads the data DAT from the memory cell array 11 and transfers the read data DAT to the input/output circuit 12. The sense amplifier module 19 applies a desired voltage to each bit line based on the data DAT received from the input/output circuit 12.

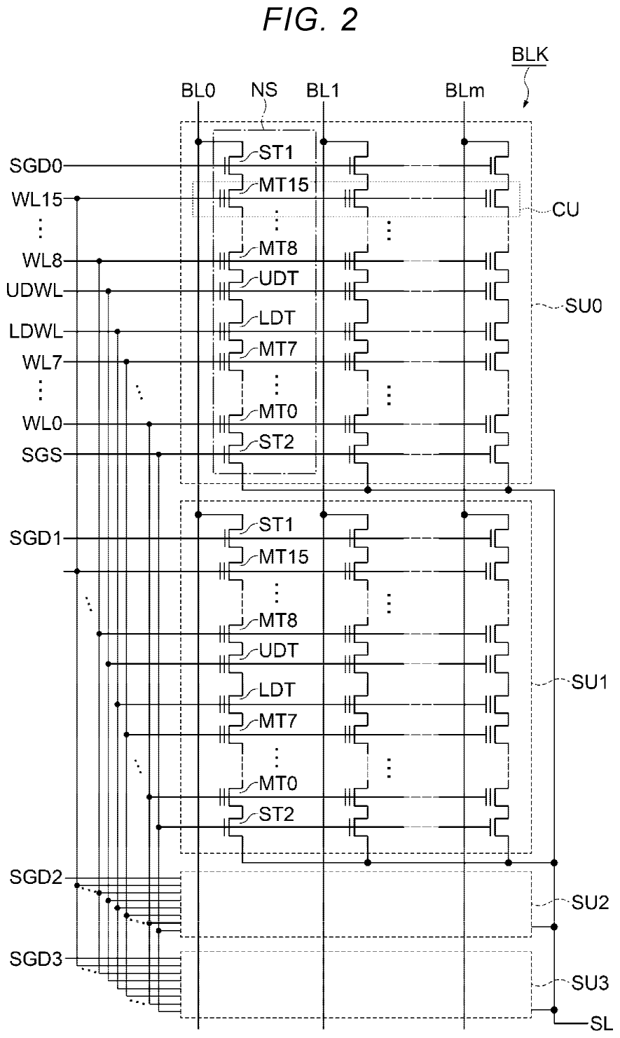

FIG. 2 is an example of a circuit configuration of the memory cell array 11 in the embodiment, and shows by means of extracting one block BLK. As shown in FIG. 2, the block BLK includes, for example, four string units SU0 to SU3.

Each string unit SU includes a plurality of NAND strings NS. The plurality of NAND strings NS is associated with bit lines BL0 to BLm (m is an integer equal to or larger than 1), respectively. In addition, each NAND string NS includes, for example, memory cell transistors MT0 to MT15, dummy transistors LDT and UDT, and select transistors ST1 and ST2.

The memory cell transistor MT includes a control gate and a charge storage layer, and stores data non-volatilely. The memory cell includes a memory cell transistor MT. Each of the dummy transistors LDT and UDT has the same configuration as the memory cell transistor MT, and is a memory cell transistor that is not used for data storage. Each of the select transistors ST1 and ST2 is used for selecting the string unit SU when performing the various operations.

In each NAND string NS, the drain of the select transistor ST1 is connected to the corresponding bit line BL. The memory cell transistors MT8 to MT15 are connected in series between the source of the select transistor ST1 and the drain of the dummy transistor UDT. The source of the dummy transistor UDT is connected to the drain of the dummy transistor LDT. The memory cell transistors MT0 to MT7 are connected in series between the source of the dummy transistor LDT and the drain of the select transistor ST2.

In the same block BLK, the control gates of each of the memory cell transistors MT0 to MT15 are commonly connected to the word lines WL0 to WL15, respectively. The control gate of the dummy transistor UDT is commonly connected to the dummy word line UDWL. The control gate of the dummy transistor LDT is commonly connected to the dummy word line LDWL. The gates of the select transistors ST1 provided in each of the string units SU0 to SU3 are commonly connected to select gate lines SGD0 to SGD3, respectively. The gate of the select transistor ST2 is commonly connected to the select gate line SGS.

Different column addresses are assigned to the bit lines BL0 to BLm, and each bit line BL is commonly connected to the select transistor ST1 of the corresponding NAND string NS among the plurality of blocks BLK. Each of the word lines WL0 to WL15 and the dummy word lines UDWL and LDWL is provided for each block BLK. The source line SL is shared among, for example, the plurality of blocks BLK.

The plurality of memory cell transistors MT connected to a same word line WL in one string unit SU is referred to as a cell unit CU. The storage capacity of the cell unit CU varies according to the number of bits of data stored in the memory cell transistor MT. For example, the cell unit CU is capable of storing 1 piece of page data when each memory cell transistor MT stores 1-bit data, and 2 pieces of page data when storing 2-bit data.

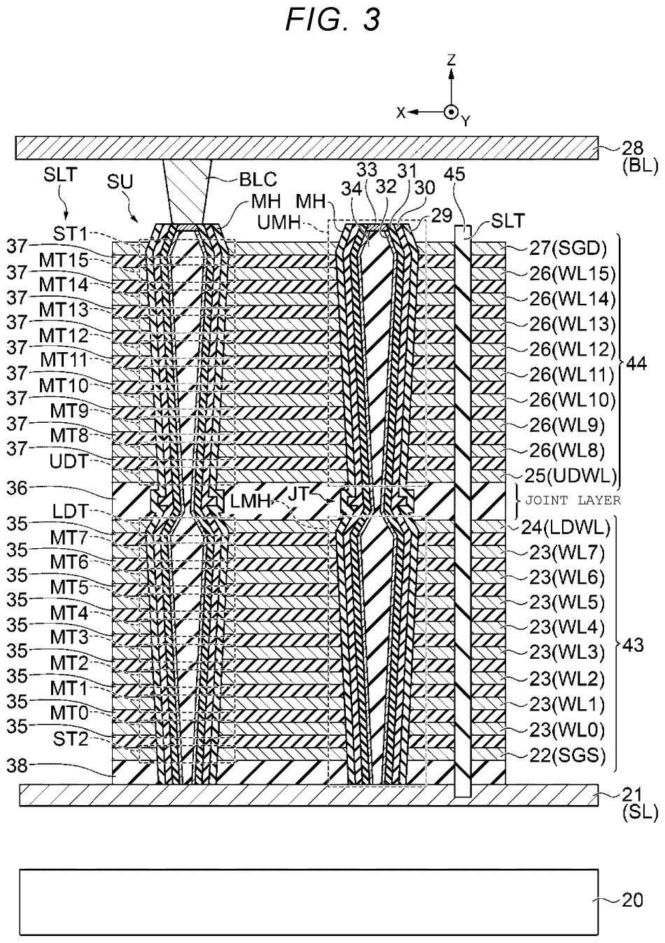

FIG. 3 is a schematic sectional view showing an example of a memory cell array 11 in at least one embodiment.

Here, an X direction (an example of a third direction), a Y direction (an example of a second direction) intersecting the X direction perpendicularly, and a Z direction (an example of a first direction) intersecting the X direction and the Y direction perpendicularly are defined.

The surface of the semiconductor substrate 20 is perpendicular to the Z direction. In other words, the surface of the semiconductor substrate 20 is parallel to an XY plane.

A conductive layer 21 is provided above the semiconductor substrate 20, for example, with an insulating film (not shown) interposed therebetween. The conductive layer 21 is formed in a plate shape along the XY plane and functions as a source line SL. A plurality of slits SLT, which are insulating films 45 along a YZ plane, are arranged on the conductive layer 21 in the X direction. The structure on the conductive layer 21 and between the adjacent slits SLT corresponds to, for example, one string unit SU.

Specifically, the conductive layer 22, eight conductive layers 23 (an example of a plurality of first conductive layers), the conductive layer 24, the conductive layer 25, eight conductive layers 26 (an example of a plurality of second conductive layers), and the conductive layer 27 are provided in order from the lower layer, on the conductive layer 21 and between the adjacent slits SLT.

An insulating layer 38 is provided between the conductive layer 21 and the conductive layer 22. An insulating layer 35 is provided between the conductive layer 22 and the conductive layer 23. Each of the insulating layers 35 (an example of a plurality of first insulating layers) is provided between each of the eight conductive layers 23. An insulating layer 35 is provided between the conductive layer 23 and the conductive layer 24. An insulating layer 36 is provided between the conductive layer 24 and the conductive layer 25. An insulating layer 37 is provided between the conductive layer 25 and the conductive layer 26. Each of the insulating layers 37 (an example of a plurality of second insulating layers) is provided between each of the eight conductive layers 26. An insulating layer 37 is provided between the conductive layer 26 and the conductive layer 27.

Each of the conductive layers 22 to 27 and the insulating layers 35 to 38 extends in the X direction and the Y direction. Each of the conductive layers 22 to 27 and the insulating layers 35 to 38 is formed in a plate shape along the XY plane.

The first stacked body 43 has the conductive layer 23 and the insulating layer 35. The second stacked body 44 has a conductive layer 26 and an insulating layer 37. The second stacked body 44 disposed along with the first stacked body 43 in the first direction.

The conductive layer 22 functions as a select gate line SGS. Each of the eight conductive layers 23 functions as word lines WL0 to WL7 in order from the lower layer. Each of the conductive layers 24 and 25 functions as dummy word lines LDWL and UDWL. Each of the eight conductive layers 26 functions as word lines WL8 to WL15 in order from the lower layer. The conductive layer 27 functions as a select gate line SGD.

Each of the plurality of memory pillars MH functions as one NAND string NS. Each memory pillar MH passes through the conductive layers 22 to 27 so as to reach the upper surface of the conductive layer 21 from the upper surface of the conductive layer 27. In addition, each memory pillar MH includes a lower pillar LMH, an upper pillar UMH, and a joint portion JT between the lower pillar LMH and the upper pillar UMH.

The upper pillar UMH is provided above the lower pillar LMH. The lower pillar LMH and the upper pillar UMH are joined (connected) to each other through the joint portion JT.

The lower pillar LMH has a portion in which a diameter or a cross-sectional area increases from the lower side toward the upper side. In addition, the upper pillar UMH has a portion in which the diameter or the cross-sectional area increases from the lower side toward the upper side.

In addition, the memory pillar MH includes, for example, a block insulating film 29, an insulating film 30, a tunnel insulating film 31, a semiconductor material 32, and a core insulating film 34. The block insulating film 29 is provided on an inner wall of the memory hole in which the memory pillar MH is formed. The insulating film 30 is provided on the inner wall of the block insulating film 29 and functions as a charge storage layer of the memory cell transistor MT. The tunnel insulating film 31 is provided on the inner wall of the insulating film 30. The semiconductor material 32 is provided on the inner wall of the tunnel insulating film 31, and a current path of the NAND is string NS formed in the semiconductor material 32. The core insulating film 34 is formed on the inner wall of the semiconductor material 32.

The block insulating film 29 contains, for example, silicon and oxygen. The insulating film 30 contains, for example, silicon and nitrogen. The tunnel insulating film 31 contains, for example, silicon, oxygen, and nitrogen. The semiconductor material 32 includes, for example, a semiconductor material such as polysilicon. The core insulating film 34 contains, for example, silicon and oxygen.

The amorphous silicon 33 is provided on the upper surface of the core insulating film 34 and is used for the electrical connection between the semiconductor material 32 and the contact plug BLC.

A portion where the memory pillar MH and the conductive layer 22 intersect functions as a select transistor ST2. Portions where the memory pillar MH and the eight conductive layers 23 intersect function as the memory cell transistors MT0 to MT7, respectively, in order from the lower layer. The memory cell provided in the memory cell transistors MT0 to MT7 is an example of the first memory cell. The portion where the memory pillar MH and the conductive layer 24 intersect functions as a dummy transistor LDT. As shown in the drawing, each of the select transistor ST2, the memory cell transistors MT0 to MT7, and the dummy transistor LDT is formed in a portion through which the lower pillar LMH passes.

A portion where the memory pillar MH and the conductive layer 25 intersect functions as a dummy transistor UDT. Portions where the memory pillar MH and the eight conductive layers 26 intersect function as the memory cell transistors MT8 to MT15, respectively, in order from the lower layer. The memory cell provided in the memory cell transistors MT8 to MT15 is an example of the second memory cell. A portion where the memory pillar MH and the conductive layer 27 intersect functions as the select transistor ST1. As shown in the drawing, each of the dummy transistor UDT, the memory cell transistors MT8 to MT15, and the select transistor ST1 is formed in a portion through which the upper pillar UMH passes.

A conductor 28 is provided above an upper layer with respect to the upper surface of the memory pillar MH with an interlayer insulating film interposed therebetween. The conductor 28 is formed in a line shape and functions as a bit line BL. The conductor 28 is electrically connected to, for example, one memory pillar MH corresponding to each string unit SU. Specifically, in each string unit SU, a conductive contact plug BLC is provided on the semiconductor material 32 in each memory pillar MH, and one conductor 28 is provided on the contact plug BLC. The connection between the memory pillar MH and the conductor 28 may be made through a plurality of contact plugs, a wiring, or the like.

The configuration of memory cell array 11 is not limited to the configuration described above. For example, each block BLK may be set to include any number of string units SU. In addition, it is possible to design any number of memory cell transistors MT, dummy transistors UDT and LDT, and select transistors ST1 and ST2 provided in each of the NAND strings NS.

In addition, the number of word lines WL, dummy word lines UDWL and LDWL, and select gate lines SGD and SGS are changed based on the number of each of the memory cell transistor MT, dummy transistors UDT and LDT, and select transistors ST1 and ST2. A plurality of the conductive layers 22 provided in each of the plurality of layers may be assigned to the select gate line SGS, and a plurality of the conductive layers 27 provided in each of the plurality of layers may be assigned to the select gate line SGD.

In addition, for example, the conductive layer 21, the insulating layer (not shown) provided between the conductive layer 21 and the semiconductor substrate 20 are not provided, and the lower pillar LMH, the insulating layer 38, and the insulating film 45 may be in direct contact with the semiconductor substrate 20.

In addition, for example, the semiconductor substrate 20 may not be provided. In addition, for example, the semiconductor substrate 20 may be provided above the conductor 28, that is, the conductor 28 may be positioned between the second stacked body 44 and the semiconductor substrate 20.

For example, the input/output circuit 12, the register unit 13, the logic controller 14, the sequencer 15, the ready/busy control circuit 16, the voltage generation circuit 17, the row decoder module 18, and the sense amplifier module 19 may be provided in the semiconductor substrate 20 or may be provided above the conductor 28. A location where the input/output circuit 12, the register unit 13, the logic controller 14, the sequencer 15, the ready/busy control circuit 16, the voltage generation circuit 17, the row decoder module 18, and the sense amplifier module 19 are provided is not particularly limited.

Regarding the configuration of the other memory cell array 11, for example, the configuration is described in U.S. patent application Ser. No. 12/407,403 filed on Mar. 19, 2009, entitled “Three dimensional stacked nonvolatile semiconductor memory”, U.S. patent application Ser. No. 12/406,524 filed on Mar. 18, 2009, entitled “Three dimensional stacked nonvolatile semiconductor memory”, U.S. patent application Ser. No. 12/679,991 filed on Mar. 25, 2010, entitled “Non-volatile semiconductor storage device and method of manufacturing the same”, and U.S. patent application Ser. No. 12/532,030 filed on Mar. 23, 2009, entitled “Semiconductor memory and method for manufacturing same”, respectively. The entire contents of these patent applications are incorporated herein by reference.

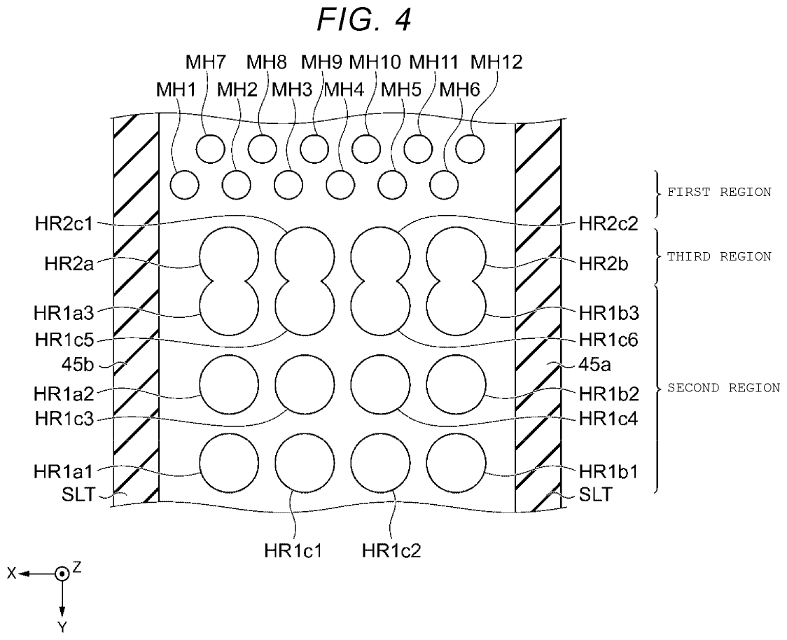

FIG. 4 is a schematic top view of the memory cell array 11 of the embodiment. The contact plug BLC and the conductor 28 shown in FIG. 3 are not shown in FIG. 4.

The slit SLT, which is the insulating film 45a (an example of the first insulating film), extends along the YZ plane in the Y direction. In addition, the slit SLT, which is the insulating film 45b (an example of the second insulating film), extends along the YZ plane in the Y direction. The insulating film 45a and the insulating film 45b are apart from each other in the X direction. The insulating film 45a and the insulating film 45b penetrate the first stacked body 43 and the second stacked body 44 in the Z direction.

Between the insulating film 45a and the insulating film 45b, a first region, a third region, and a second region are provided in order in the Y direction. The third region is provided between the first region and the second region.

The first region is provided with a memory pillar MH1, a memory pillar MH2, a memory pillar MH3, a memory pillar MH4, a memory pillar MH5, a memory pillar MH6, a memory pillar MH7, a memory pillar MH8, a memory pillar MH9, a memory pillar MH10, a memory pillar MH11, and a memory pillar MH12. As described with reference to FIG. 3, each memory pillar MH has a lower pillar LMH (an example of a first memory pillar) and an upper memory pillar (an example of a second memory pillar). The number and arrangement of the memory pillars MH in the first region are not limited to those shown in FIG. 4.

The second region is provided with a columnar portion HR1. The diameter or the cross-sectional area of the columnar portion HR1 in the XY plane is larger than the diameter or the cross-sectional area of the memory pillar MH. Here, the comparison between the diameter or the cross-sectional area of the columnar portion HR1 and the diameter or the cross-sectional area of the memory pillar MH is performed in a portion at which the same word line WL, the dummy word line UDWL, or the dummy word line LDWL pass.

Here, the second region is provided with a columnar portion HR1a1, a columnar portion HR1a2, a columnar portion HR1a3, a columnar portion HR1b1, a columnar portion HR1b2, a columnar portion HR1b3, a columnar portion HR1c1, a columnar portion HR1c2, a columnar portion HR1c3, a columnar portion HR1c4, a columnar portion HR1c5, and a columnar portion HR1c6. The columnar portion HR1c1 and the columnar portion HR1c2 are provided between the columnar portion HR1a1 and the columnar portion HR1b1. The columnar portion HR1c3 and the columnar portion HR1c4 are provided between the columnar portion HR1a2 and the columnar portion HR1b2. The columnar portion HR1c5 and the columnar portion HR1c6 are provided between the columnar portion HR1a3 and the columnar portion HR1b3.

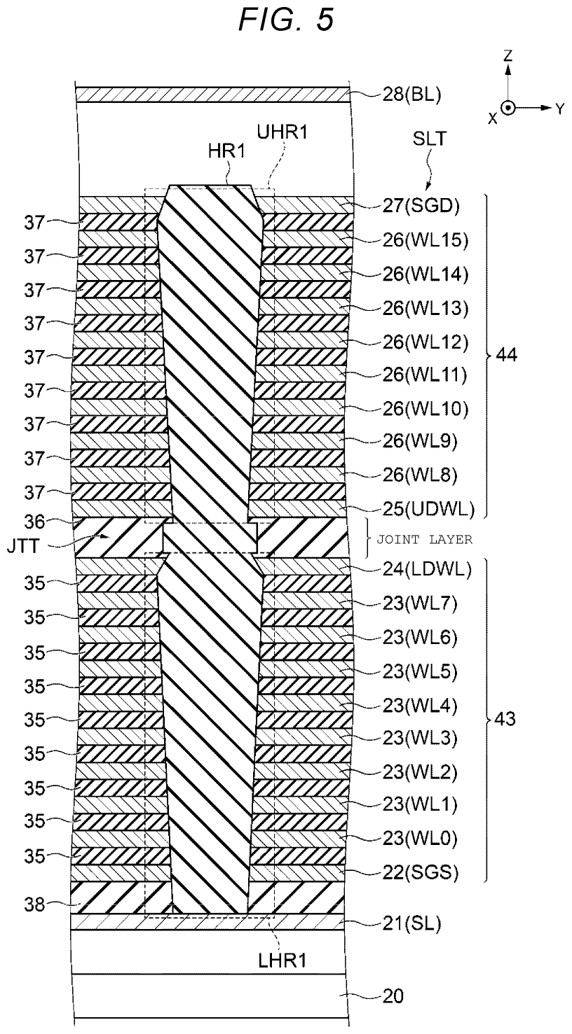

FIG. 5 is a schematic sectional view of the columnar portion HR1.

Each columnar portion HR1 passes through the conductive layers 22 to 27, the insulating layer 38, and the insulating layers 35 to 37 so as to reach the upper surface of the conductive layer 21 from the upper surface of the conductive layer 27. In addition, each columnar portion HR1 includes a lower columnar portion LHR1, an upper columnar portion UHR1, and a joint portion JTT between the lower columnar portion LHR1 and the upper columnar portion UHR1. For example, the insulating layer (not shown) is not provided in the conductive layer 21 and between the conductive layer 21 and the semiconductor substrate 20, and the lower columnar portion LHR1 and the insulating layer 38 may be in direct contact with the semiconductor substrate 20.

The upper columnar portion UHR1 is provided above the lower columnar portion LHR1. A space between the lower columnar portion LHR1 and the upper columnar portion UHR1 is joined (connected) through the joint portion JTT.

The lower columnar portion LHR1 has a portion in which the diameter or the cross-sectional area increases from the lower side toward the upper side. In addition, the upper columnar portion UHR1 has a portion in which the diameter or the cross-sectional area increases from the lower side toward the upper side.

Here, an insulating material containing, for example, oxygen and silicon is formed in the columnar portion HR1a1, the columnar portion HR1a2, the columnar portion HR1a3, the columnar portion HR1b1, the columnar portion HR1b2, and the columnar portion HR1b3. In other words, the columnar portion HR1a1, the columnar portion HR1a2, the columnar portion HR1a3, the columnar portion HR1b1, the columnar portion HR1b2, and the columnar portion HR1b3 include an insulating material which is, for example, silicon oxide.

On the other hand, the material contained in the memory pillar MH is formed in the columnar portion HR1c1, the columnar portion HR1c2, the columnar portion HR1c3, the columnar portion HR1c4, the columnar portion HR1c5, and the columnar portion HR1c6. In other words, the columnar portion HR1c1, the columnar portion HR1c2, the columnar portion HR1c3, the columnar portion HR1c4, the columnar portion HR1c5, and the columnar portion HR1c6 include the material provided in the memory cell. Here, the material provided in the memory cell is, for example, the block insulating film 29, the insulating film 30, the tunnel insulating film 31, the conductive semiconductor material 32, and the core insulating film 34.

The third region is provided with a columnar portion HR2. The diameter or the cross-sectional area of the columnar portion HR2 in the XY plane is larger than the diameter or the cross-sectional area of the memory pillar MH. Here, the comparison between the diameter or the cross-sectional area of the columnar portion HR2 and the diameter or the cross-sectional area of the memory pillar MH is performed in a portion at which the same word line WL, the dummy word line UDWL, or the dummy word line LDWL pass.

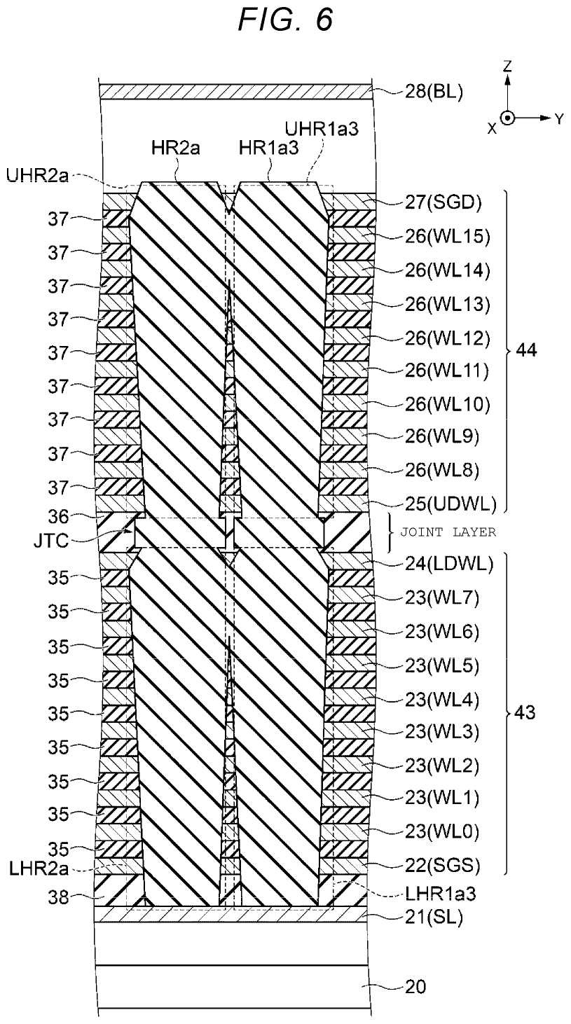

FIG. 6 is a schematic sectional view of the columnar portion HR2. In FIG. 6, the columnar portion HR2a as the columnar portion HR2 and the columnar portion HR1a3 are collectively shown.

Each columnar portion HR2 passes through the conductive layers 22 to 27, the insulating layer 38, and the insulating layers 35 to 37 so as to reach the upper surface of the conductive layer 21 from the upper surface of the conductive layer 27. In addition, each columnar portion HR2 includes a lower columnar portion LHR2, an upper columnar portion UHR2, and a joint portion JTC between the lower columnar portion LHR2 and the upper columnar portion UHR2.

The upper columnar portion UHR2 is provided above the lower columnar portion LHR2. A space between the lower columnar portion LHR2 and the upper columnar portion UHR2 is joined (connected) through the joint portion JTC. For example, an outer peripheral length or a cross-sectional area of the joint portion JTC is larger than an outer peripheral length or a cross-sectional area of the joint portion between the lower columnar portion LHR2 and the joint portion JTC. For example, an outer peripheral length or a cross-sectional area of the joint portion JT is larger than an outer peripheral length or a cross-sectional area of the joint portion between the upper columnar portion UHR2 and the joint portion JT.

The lower columnar portion LHR2 has a portion in which the diameter or the cross-sectional area increases from the lower side toward the upper side. In addition, the upper columnar portion UHR2 has a portion in which the diameter or the cross-sectional area increases from the lower side toward the upper side.

An upper portion of the lower columnar portion LHR2a is in contact with an upper portion of the lower columnar portion LHR1a3 in the Y direction. The first stacked body 43 provided under the portion where the upper portion of the lower columnar portion LHR2a and the upper portion of the lower columnar portion LHR1a3 are in contact with each other has a shape in which the length in the Y direction is shortened from the lower side toward the upper side (to a direction from the first stacked body 43 toward the second stacked body 44) in the Z direction. The number of the conductive layers 23 and the number of the insulating layers 35 provided in the first stacked body 43 provided under the portion where the upper portion of the lower columnar portion LHR2a and the upper portion of the lower columnar portion LHR1a3 are in contact with each other are not limited to those shown in FIG. 6.

Similarly, the upper portion of the lower columnar portion LHR2c1 is in contact with the upper portion of the lower columnar portion LHR1c5 in the Y direction. The first stacked body 43 provided under a portion where the upper portion of the lower columnar portion LHR2c1 and the upper portion of the lower columnar portion LHR1c5 are in contact with each other has a shape in which the length in the Y direction is shortened from the lower side toward the upper side in the Z direction. The upper portion of the lower columnar portion LHR2c2 is in contact with the upper portion of the lower columnar portion LHR1c6 in the Y direction. The first stacked body 43 provided under a portion where the upper portion of the lower columnar portion LHR2c2 and the upper portion of the lower columnar portion LHR1c6 are in contact with each other has a shape in which the length in the Y direction is shortened from the lower side toward the upper side in the Z direction. The upper portion of the lower columnar portion LHR2b is in contact with the upper portion of the lower columnar portion LHR1b3 in the Y direction. The first stacked body 43 provided under a portion where the upper portion of the lower columnar portion LHR2b and the upper portion of the lower columnar portion LHR1b3 are in contact with each other has a shape in which the length in the Y direction is shortened from the lower side toward the upper side in the Z direction.

In addition, the upper portion of the upper columnar portion UHR2a is in contact with the upper portion of the upper columnar portion UHR1a3 in the Y direction. The second stacked body 44 provided under a portion where the upper portion of the upper columnar portion UHR2a and the upper portion of the upper columnar portion UHR1a3 are in contact with each other has a shape in which the length in the Y direction is shortened from the lower side toward the upper side (to a direction from the first stacked body 43 toward the second stacked body 44) in the Z direction. The number of the conductive layers 26 and the number of the insulating layers 37 provided in the second stacked body 44 provided under the portion where the upper portion of the upper columnar portion UHR2a and the upper portion of the upper columnar portion UHR1a3 are in contact with each other are not limited to those shown in FIG. 6.

Similarly, the upper portion of the upper columnar portion UHR2c1 is in contact with the upper portion of the upper columnar portion UHR1c5 in the Y direction. The second stacked body 44 provided under the portion where the upper portion of the upper columnar portion UHR2c1 and the upper portion of the upper columnar portion UHR1c5 are in contact with each other has a shape in which the length in the Y direction is shortened from the lower side toward the upper side in the Z direction. The upper portion of the upper columnar portion UHR2c2 is in contact with the upper portion of the upper columnar portion UHR1c6 in the Y direction. The second stacked body 44 provided under the portion where the upper portion of the upper columnar portion UHR2c2 and the upper portion of the upper columnar portion UHR1c6 are in contact with each other has a shape in which the length in the Y direction is shortened from the lower side toward the upper side in the Z direction. The upper portion of the upper columnar portion UHR2b is in contact with the upper portion of the upper columnar portion UHR1b3 in the Y direction. The second stacked body 44 provided under the portion where the upper portion of the upper columnar portion UHR2b and the upper portion of the upper columnar portion UHR1b3 are in contact with each other has a shape in which the length in the Y direction is shortened from the lower side toward the upper side in the Z direction.

Here, an insulating material containing, for example, oxygen and silicon is formed in the columnar portion HR2a and the columnar portion HR2b. In other words, the columnar portion HR2a and the columnar portion HR2b include an insulating material which is, for example, silicon oxide.

On the other hand, a material contained in the memory pillar MH is formed in the columnar portion HR2c1 and the columnar portion HR2c2. In other words, the columnar portion HR2c1 and the columnar portion HR2c2 include the material provided in the memory cell. Here, the material provided in the memory cell is, for example, the block insulating film 29, the insulating film 30, the tunnel insulating film 31, the conductive semiconductor material 32, and the core insulating film 34.

In summary, the plurality of first columnar portions (LHR1) have the fifth columnar portion (LHR1b3) including the insulating material, the sixth columnar portion (LHR1a3) provided apart from the fifth columnar portion (LHR1b3) in the third direction (X direction) and including the insulating material, and the seventh columnar portions (LHR1c5, LHR1c6) provided between the fifth columnar portion (LHR1b3) and the sixth columnar portion (LHR1a3) and including the material provided in the first memory cell, the plurality of second columnar portions (UHR1) have the eighth columnar portion (UHR1b3) including the insulating material, the ninth columnar portion (UHR1a3) provided apart from the eighth columnar portion (UHR1b3) in the third direction (X direction) and including the insulating material, and the tenth columnar portions (UHR1c5, UHR1c6) provided between the eighth columnar portion (UHR1b3) and the ninth columnar portion (UHR1a3) and including the material provided in the second memory cell, the plurality of third columnar portions (LHR2) have the eleventh columnar portion (LHR2b) including the insulating material and being in contact with the fifth columnar portion (LHR1b3), the twelfth columnar portion (LHR2a) provided apart from the eleventh columnar portion (LHR2b) in the third direction, including the insulating material, and being in contact with the sixth columnar portion (LHR1a3), and the thirteenth columnar portion (LHR2c1, LHR2c2) provided between the eleventh columnar portion (LHR2b) and the twelfth columnar portion (LHR2a), including the material provided in the first memory cell and being in contact with the seventh columnar portions (LHR1c5, LHR1c6), and the plurality of fourth columnar portions (UHR2) have the fourteenth columnar portion (UHR2b) including the insulating material and being in contact with the eighth columnar portion (UHR1b3), the fifteenth columnar portion (UHR2a) provided apart from the fourteenth columnar portion (UHR2b) in the third direction and including the insulating material, and the sixteenth columnar portion (UHR2c1, UHR2c2) provided between the fourteenth columnar portion (UHR2b) and fifteenth columnar portion (UHR2a), including the material included the second memory cell, and being in contact with the tenth columnar portion (UHR1c5, UHR1c6).

The columnar portion HR1 and the columnar portion HR2 are used for reinforcing the first stacked body 43 and the second stacked body 44 when the sacrificial layer 52 and the sacrificial layer 56 used in the manufacturing step described later are replaced.

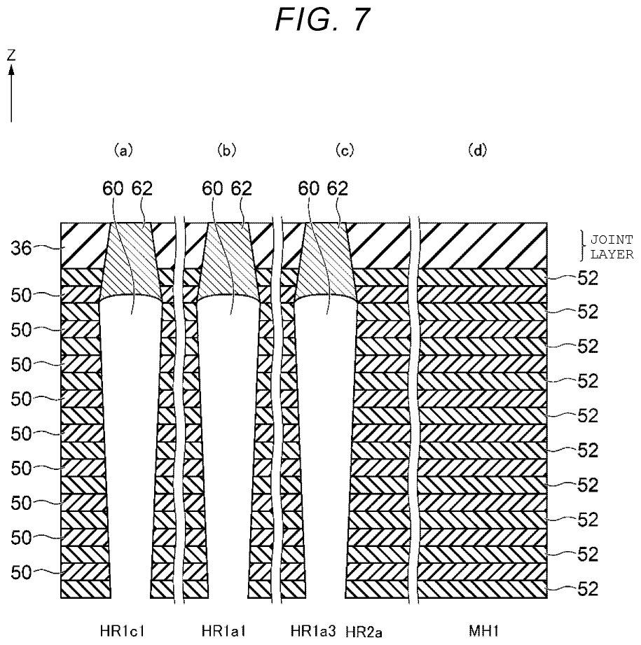

FIGS. 7 to 18 are schematic sectional views showing manufacturing steps of the semiconductor storage device of the embodiment.

Here, a method for manufacturing the columnar portion HR1c1, the columnar portion HR1a1, the columnar portion HR1a3, the columnar portion HR2a, and the memory pillar MH1 will be described as an example. The shapes of the columnar portion HR1c1, the columnar portion HR1a1, the columnar portion HR1a3, the columnar portion HR2a, and the memory pillar MH1 may not match the shapes shown in FIGS. 3 to 6.

First, a hole 60 for forming the columnar portion HR1 is formed in the insulating layer 36 formed in the sacrificial layer 52 and in the multilayer film in which the sacrificial layer 52 and the insulating layer 50 are alternately formed in one by one. The insulating layer 50 is, for example, a film containing oxygen and silicon, and is a film to be the insulating layer 35. The sacrificial layer 52 is, for example, a film containing nitrogen and silicon, and is a film to be replaced with the conductive layer 22, the conductive layer 23, and the conductive layer 24.

Specifically, for example, a hard mask (not shown) including carbon is formed on the insulating layer 36, and a photoresist (not shown) is formed on the hard mask. After that, the photoresist is processed by photolithography method. After that, a hard mask is processed using the processed photoresist by a reactive ion etching (RIE) method. After that, the photoresist is removed. After that, the hole 60 is formed in the multilayer film in which the insulating layer 50 and the sacrificial layer 52 are alternately formed one by one and in the insulating layer 36 using the processed hard mask by the RIE method. After that, the hard mask is removed by ashing method.

After that, a carbon material 62 is formed on the upper portion of the hole 60. After that, the carbon material 62 formed on the insulating layer 36 is removed by etching back. As a result, the carbon material 62 remains in the hole 60 (FIG. 7).

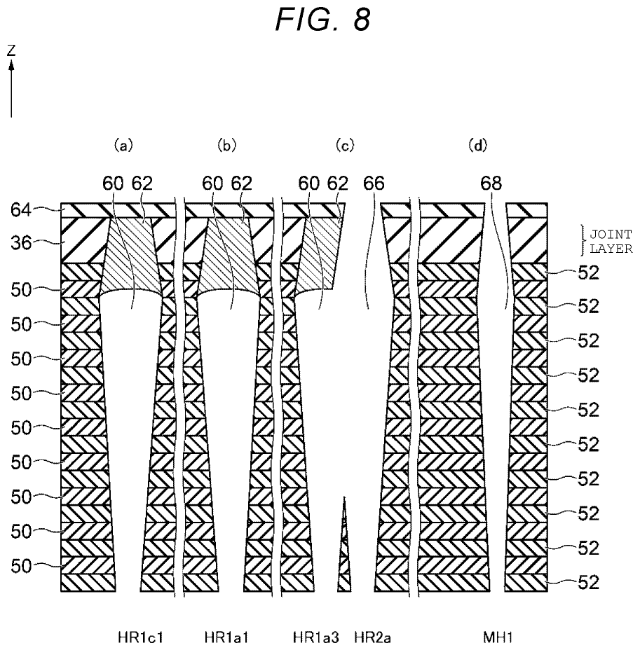

After that, a hole 66 in which the columnar portion HR2 is formed and a hole 68 in which the memory pillar MH is formed are formed in the multilayer film in which the insulating layer 50 and the sacrificial layer 52 are alternately formed one by one and in the insulating layer 36 formed on the multilayer film (FIG. 8).

Specifically, the hard mask 64 containing carbon is formed on the insulating layer 36. After that, a photoresist (not shown) is formed on the hard mask 64. Next, the photoresist is processed by photolithography method. After that, the hard mask 64 is processed using the processed photoresist by the RIE method. After that, the photoresist is removed. After that, the hole 66 and the hole 68 are formed in the multilayer film in which the insulating layer 50 and the sacrificial layer 52 are formed one by one and in the insulating layer 36 formed on the multilayer film by the RIE method using the processed hard mask 64.

At this time, the hole 66 is formed such that the upper portion of the hole 66 is in contact with the upper portion of a part of the hole 60. A part of the multilayer film in which the insulating layer 50 and the sacrificial layer 52 are alternately formed one by one remains under a portion where the upper portion of the hole 66 and the upper portion of the part of the hole 60 are in contact with each other. In addition, the diameter or the cross-sectional area of the hole 68 is made smaller than the diameter or the cross-sectional area of the hole 60 and the hole 66.

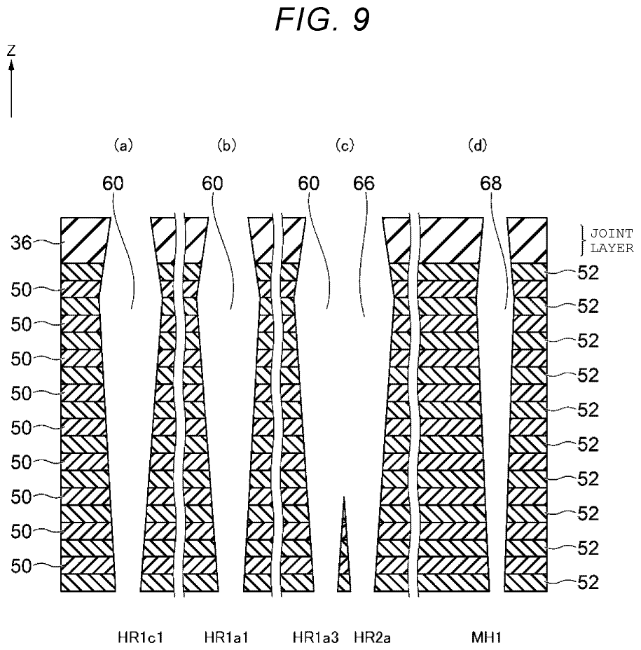

After that, the hard mask 64 and the carbon material 62 are removed by ashing method (FIG. 9).

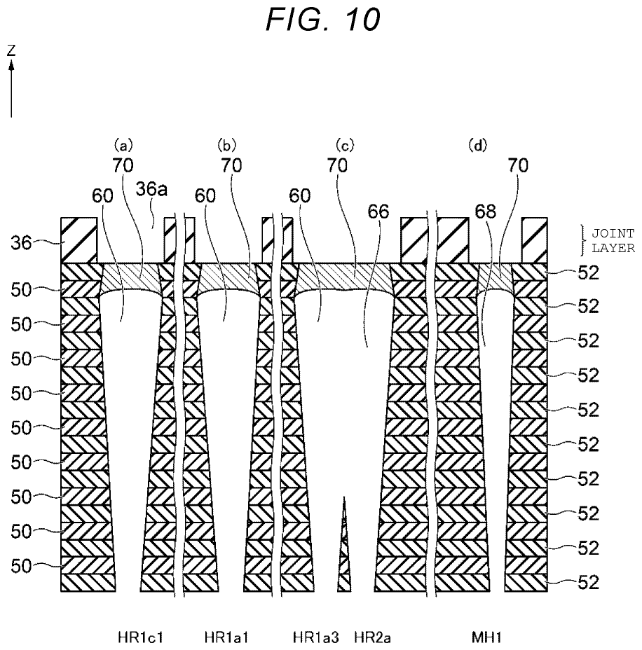

After that, the sacrificial carbon 70 is deposited and then etched back. After that, the holes 36a for forming the joint portions JT, JTT, and JTC are formed in the insulating layer 36 (FIG. 10).

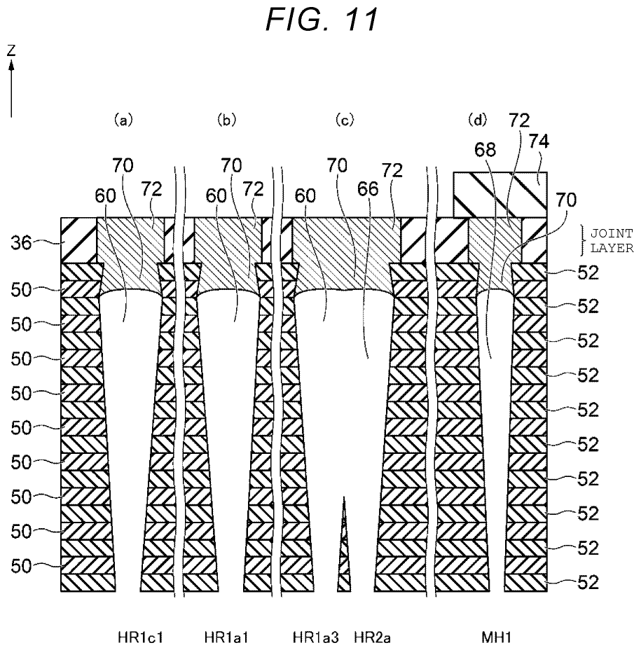

After that, the sacrificial carbon 72 is deposited on the sacrificial carbon 70 and then etched back. After that, a photoresist 74 is formed on the hole 68 in which the memory pillar MH is formed (FIG. 11).

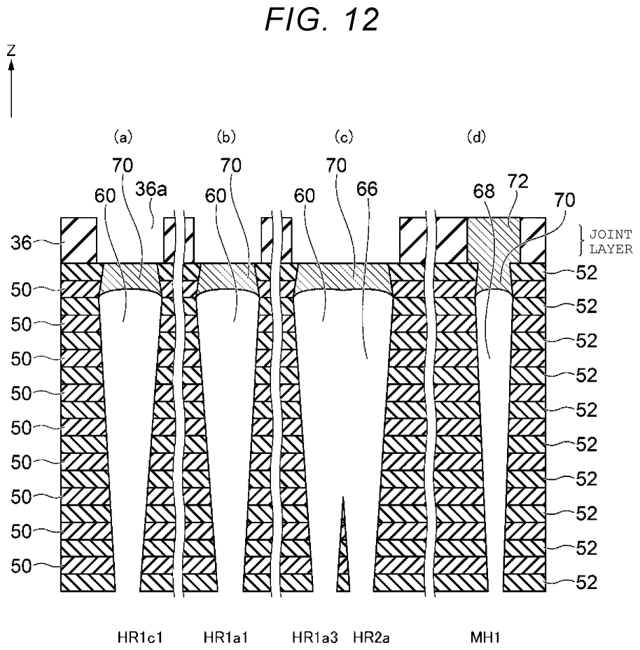

After that, the photoresist 74 and the sacrificial carbon 72 other than the sacrificial carbon 72 under the photoresist 74 are removed by etching back. Here, the film thickness of the photoresist 74 is preferably controlled to a film thickness that may be removed together with the sacrificial carbon 72 at the same time in the etch back process (FIG. 12).

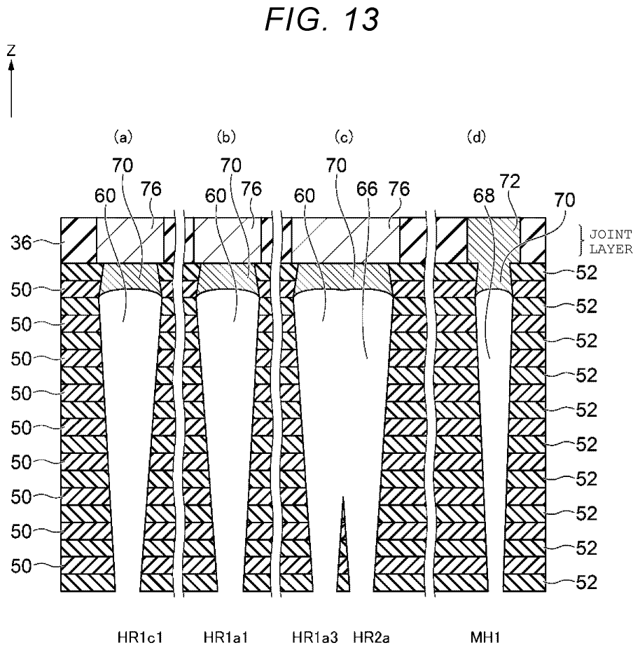

Next, amorphous silicon 76 is deposited at the location from which the sacrificial carbon 72 has been removed, and the upper surface of the insulating layer 36 is flattened by etching back (FIG. 13).

After that, the multilayer film in which the sacrificial layer 56 and the insulating layer 54 are alternately formed one by one on the insulating layer 36, and the insulating layer 42 formed on the sacrificial layer 56 of the multilayer film is formed. The insulating layer 54 is, for example, a film containing oxygen and silicon, and is a film to be the insulating layer 37. The sacrificial layer 56 is, for example, a film containing nitrogen and silicon, and is a film to be replaced with the conductive layer 25, the conductive layer 26, and the conductive layer 27.

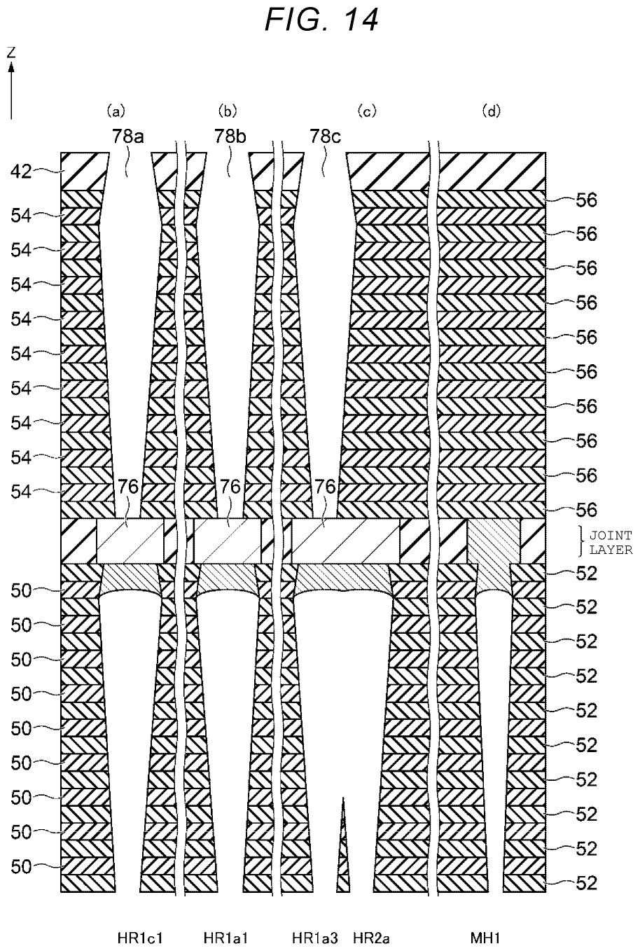

After that, the hole 78 is formed in the multilayer film in which the insulating layer 54 and the sacrificial layer 56 are alternately formed one by one and in the insulating layer 42 formed on the sacrificial layer 56 of the multilayer film. The hole 78 is, for example, a hole in which UHR1c1, UHR1a1, and UHR1a3 are formed (FIG. 14).

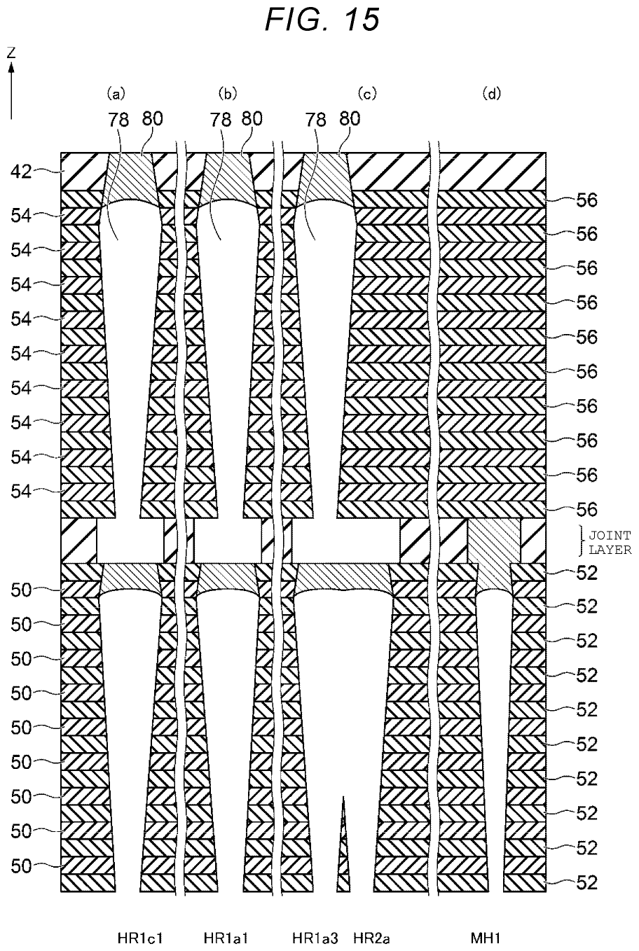

After that, the amorphous silicon 76 is removed by, for example, wet etching. After that, a carbon material 80 is formed on the upper portion of the hole 78. After that, the carbon material 80 formed on the insulating layer 42 is removed by etching back. As a result, the carbon material 80 remains in the hole 78 (FIG. 15).

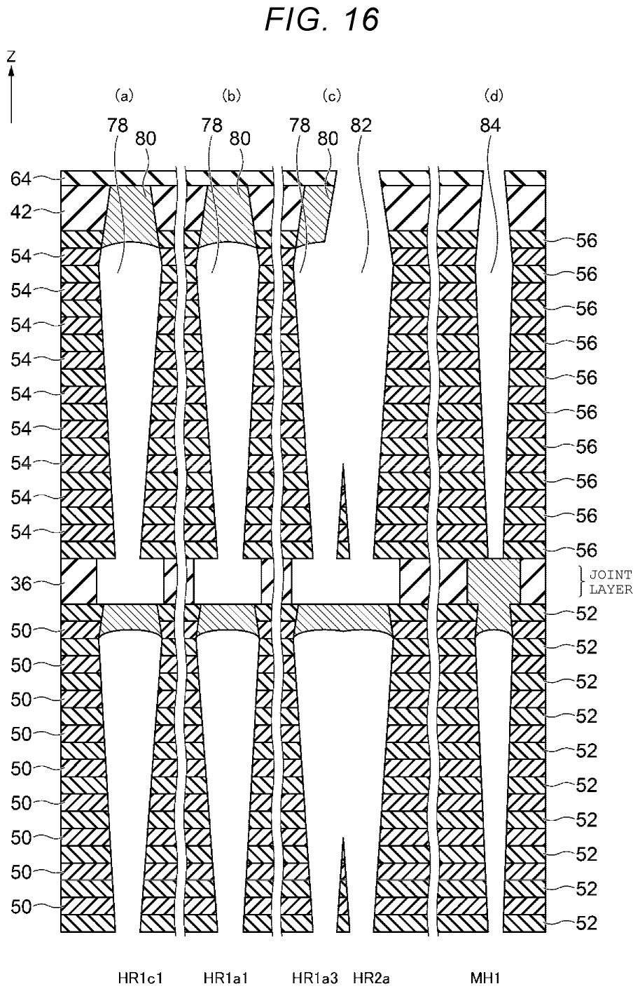

Next, the hole 82 and the hole 84 are formed in the same manner as in the process shown in FIG. 8. At this time, the hole 82 is formed so that the upper portion of the hole 82 is connected to the upper portion of a part of the hole 78. A part of the multilayer film in which the insulating layer 54 and the sacrificial layer 56 are alternately formed one by one remains under the connected upper portion of the hole 82 and the part of the hole 78. In addition, the diameter or the cross-sectional area of the hole 84 is made smaller than the diameter or the cross-sectional area of the hole 78 and the hole 82 (FIG. 16).

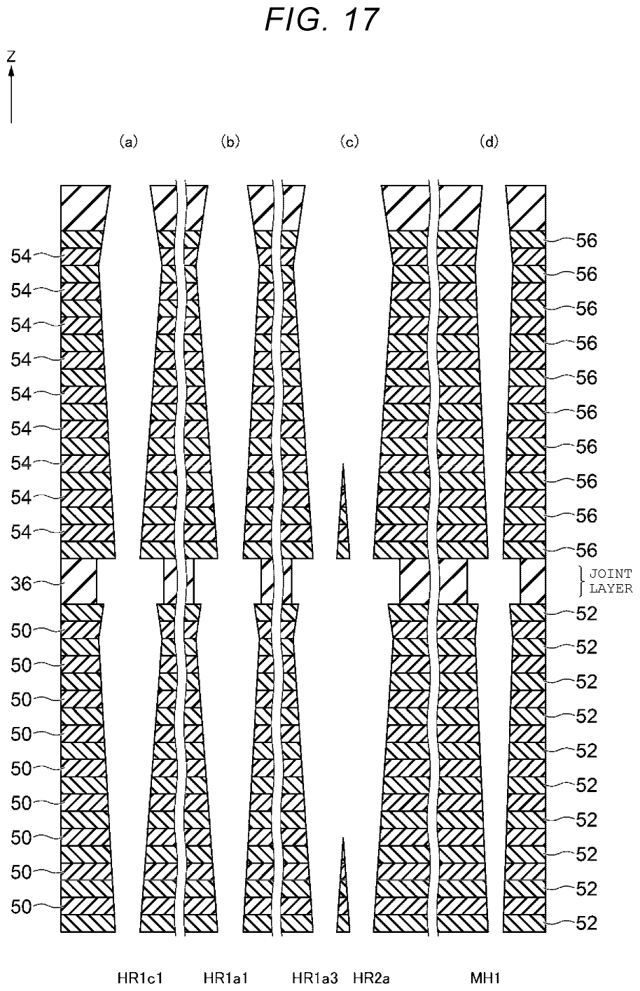

After that, the sacrificial carbon 70, the sacrificial carbon 72, the carbon material 80, and the hard mask 64 are removed by ashing method (FIG. 17).

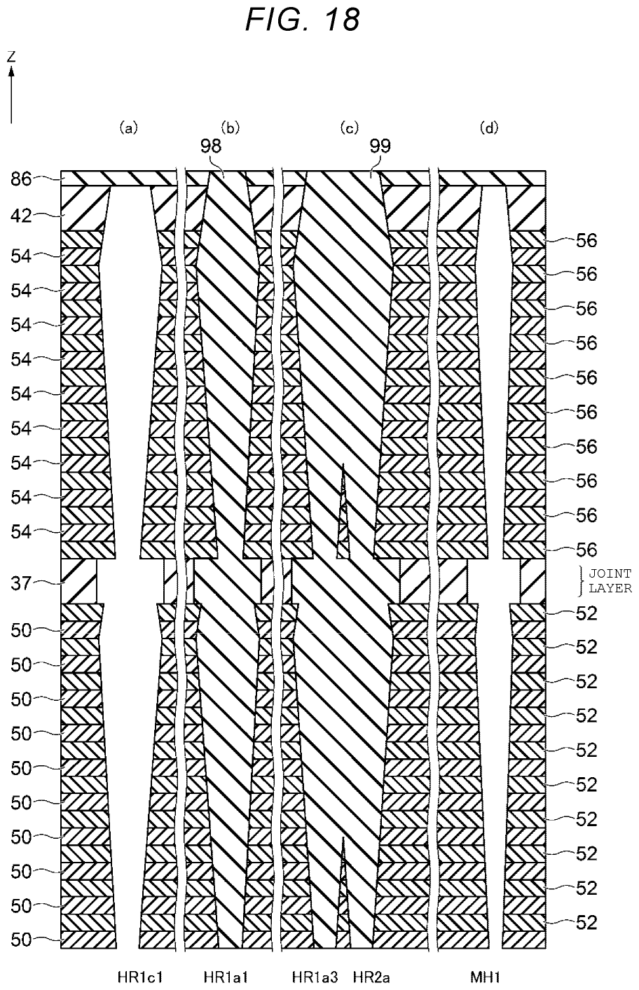

After that, the hard mask 86 as shown in FIG. 18 is formed, and then HR1a1 is filled with an insulating material containing oxygen and silicon. Similarly, HR1a2, HR1a3, HR2a, HR1b1, HR1b2, HR1b3, and HR2b are filled with the insulating material 98 or the insulating material 99 containing oxygen and silicon (FIG. 18).

After that, the hard mask 86 is removed by ashing method. After that, the amorphous silicon 33 and the structures contained in the memory pillar MH are formed in the memory pillar MH, HR1c1, HR1c2, HR1c3, HR1c4, HR2c1, and HR2c2.

After that, the replacement from the sacrificial layer 52 to the conductive layer 22, the conductive layer 23, and the conductive layer 24 and the replacement from the sacrificial layer 56 to the conductive layer 25, the conductive layer 26, and the conductive layer 27 are performed. For example, the sacrificial layer 52 and the sacrificial layer 56 are removed by wet etching using phosphoric acid (H₃PO₄) through an opening (not shown) through which the insulating film 45a and the insulating film 45b to be formed later. After that, for example, the conductive layer 22, the conductive layer 23, the conductive layer 24, the conductive layer 25, the conductive layer 26, and the conductive layer 27, each of which has tungsten (W) and a barrier metal film around the tungsten, are formed by a CVD method. After that, the insulating film 45a and the insulating film 45b are formed in the opening (not shown) used for the wet etching.

After that, the conductive contact plug BLC and the conductor 28 are appropriately formed on the insulating layer 42 to obtain the semiconductor storage device of the embodiment.

After that, the operation and effect of the semiconductor storage device of the embodiment will be described.

As a comparative example, in the manufacturing step, it is considered that the hole in which the memory pillar MH is formed and the hole in which the columnar portion HR is formed are formed in separate steps. For example, when the diameter or the cross-sectional area of the hole in which the memory pillar MH is formed and the diameter or the cross-sectional area of the hole in which the columnar portion HR is formed are different as in the semiconductor storage device of the embodiment, the hole may be formed more quickly and accurately by manufacturing in another step.

Here, when the contact between the hole in which the memory pillar MH is formed and the hole in which the columnar portion HR is formed is not allowed, it is preferable that the distance between the hole in which the memory pillar MH is formed and the hole in which the columnar portion HR is formed is sufficiently secured in the Y direction shown in FIG. 4, for example. This is because a shift may occur between the position of the hole of the mask for forming the hole of the memory pillar MH and the position of the hole of the mask for forming the hole of the columnar portion HR.

However, when the sacrificial layer 52 and the sacrificial layer 56 are removed for replacement of the sacrificial layer 52 and the sacrificial layer 56, there is a concern that the structure in which the insulating layer 50 is stacked and the structure in which the insulating layer 54 is stacked between the hole in which the memory pillar MH is formed and the hole in which the columnar portion HR is formed may not be maintained and may be broken. The structure in which the insulating layer 50 is stacked and the structure in which the insulating layer 54 is stacked are structures having low strength because the conductive film between the insulating layers 50 and the conductive film between the insulating layers 54 are not provided. Therefore, when the distance between the hole in which the memory pillar MH is formed and the hole in which the columnar portion HR is formed is long, there is a concern that the insulating layer 50 or the insulating layer 54 may be bent and broken.

Therefore, the semiconductor storage device of the embodiment includes a plurality of first columnar portions, each of which penetrates a first insulating film in between the first insulating film and a second insulating film in a first direction, is provided apart from a plurality of first memory pillars in a second direction, and has a cross-sectional area larger than a cross-sectional area of the first memory pillar in a first surface parallel to the second direction and a third direction, a plurality of second columnar portions, each of which penetrates a second insulating film in between the first insulating film and the second insulating film in the first direction, is provided apart from a plurality of second memory pillars in the second direction, has a cross-sectional area larger than a cross-sectional area of the second memory pillar in a second surface parallel to the second direction and the third direction, and is connected to the plurality of first columnar portions in the first direction, a plurality of third columnar portions, each of which penetrates the first stacked body in between the first memory pillar and the first columnar portion in the first direction, is apart from the first memory pillar, is provided in contact with the first columnar portion in the second direction, and has a cross-sectional area larger than the cross-sectional area of the first memory pillar in the first surface, a plurality of fourth columnar portions, each of which penetrates the second stacked body in between the second memory pillar and the second columnar portion in the first direction, is apart from the second memory pillar, is provided in contact with the second columnar portions in the second direction, and has a cross-sectional area larger than the cross-sectional area of the second memory pillar in the second surface, and is connected to the plurality of third columnar portions in the first direction.

In other words, in the semiconductor storage device of the embodiment, the columnar portion HR2 for bringing the columnar portion HR1 into contact with the columnar portion HR1 is provided between the memory pillar MH and the columnar portion HR1.

The memory cell is not provided in the columnar portion HR2. Therefore, the columnar portion HR2 may be in contact with the columnar portion HR1.

In addition, usually, the formation of the structure of the memory pillar MH in the columnar portion HR2 is performed at the same time as the formation of the other memory pillars MH. At the time of the formation, the columnar portion HR2 having a large diameter or cross-sectional area is provided at the end portion of the series of memory pillars MH, so that the formation of the memory pillar MH is facilitated.

The formation of the hole 78c for forming the upper columnar portion UHR1 in the columnar portion HR1 in contact with the columnar portion HR2 is performed using the amorphous silicon 76 as a stopper film. When the amorphous silicon 76 is not provided, there is a concern that the shape of the lower columnar portion HR2a may be unintentionally deformed when the hole 78 is formed. In addition, for example, when the conductive layer 21 is provided, there is a concern that the conductive layer 21 may be damaged.

In addition, in order to insulate, the columnar portion HR1a1, the columnar portion HR1a2, the columnar portion HR1a3, the columnar portion HR2a, the columnar portion HR1b1, the columnar portion HR1b2, the columnar portion HR1b3, and the columnar portion HR2b in the vicinity of the insulating film 45 include an insulating material. On the other hand, the columnar portion HR1c1, the columnar portion HR1c2, the columnar portion HR1c3, the columnar portion HR1c4, the columnar portion HR1c5, the columnar portion HR1c6, the columnar portion HR2c1, and the columnar portion HR2c2 provided apart from the insulating film 45 include a material provided in the memory cell. This is because, when the columnar portion HR1c1, the columnar portion HR1c2, the columnar portion HR1c3, the columnar portion HR1c4, the columnar portion HR1c5, the columnar portion HR1c6, the columnar portion HR2c1, and the columnar portion HR2c2 provided apart from the insulating film 45 are made to include the insulating material, there is a concern that the structure in which the insulating layer 50 is stacked and the structure in which the insulating layer 54 is stacked in the vicinity of the columnar portion HR may be destroyed without being maintained during the above-described replacement.

According to the semiconductor storage device of the embodiment, it is possible to provide a semiconductor storage device that is easily manufactured.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first stacked body including a plurality of first conductive layers and a plurality of first insulating layers alternately stacked in a first direction, the first stacked body extending in a second direction intersecting the first direction and a third direction, the third direction intersecting the first direction and the second direction;
second stacked body disposed along with the first stacked body in the first direction, including a plurality of second conductive layers and a plurality of second insulating layers alternately stacked in the first direction, and extending in the second direction and the third direction;
a first insulating film that penetrates the first stacked body and the second stacked body in the first direction and extends in the second direction;
a second insulating film disposed apart from the first insulating film in the third direction, penetrates the first stacked body and the second stacked body in the first direction, and extends in the second direction;
a plurality of first memory pillars disposed between the first insulating film and the second insulating film, each of the first memory pillars: (i) penetrates the first stacked body in the first direction, and (ii) has a plurality of first memory cells;
a plurality of second memory pillars disposed between the first insulating film and the second insulating film,
each of the plurality of second memory pillars:
penetrates the second stacked body in the first direction,
has a plurality of second memory cells, and
is connected to the first memory pillars in the first direction;
a plurality of first columnar portions, each of the plurality of first columnar portions:
penetrates the first stacked body in the first direction in between the first insulating film and the second insulating film,
is disposed apart from the plurality of first memory pillars in the second direction, and
has a cross-sectional area larger than a cross-sectional area of the first memory pillar in a first surface parallel to the second direction and the third direction;
a plurality of second columnar portions, each of the plurality of second columnar portions:
penetrates the second stacked body in the first direction in between the first insulating film and the second insulating film,
is disposed apart from the plurality of second memory pillars in the second direction,
has a cross-sectional area larger than a cross-sectional area of the second memory pillar in a second surface parallel to the second direction and the third direction, and
is connected to the plurality of first columnar portions in the first direction;
a plurality of third columnar portions, each of the plurality of third columnar portions:
penetrates the first stacked body in the first direction in between the first memory pillar and the first columnar portion,
is apart from the first memory pillars,
is disposed in contact with the first columnar portion in the second direction, and
has a cross-sectional area larger than the cross-sectional area of the first memory pillar in the first surface; and
a plurality of fourth columnar portions, each of the plurality of fourth columnar portions:
penetrates the second stacked body in the first direction in between the second memory pillar and the second columnar portion,
is apart from the second memory pillar,
is disposed in contact with the second columnar portion in the second direction,
has a cross-sectional area larger than the cross-sectional area of the second memory pillar in second surface, and
is connected to the plurality of third columnar portions in the first direction.

2. The semiconductor storage device according to claim 1, wherein
the plurality of first columnar portions includes:
a fifth columnar portion including an insulating material,
a sixth columnar portion disposed apart from the fifth columnar portion in the third direction and including an insulating material, and
a seventh columnar portion disposed between the fifth columnar portion and the sixth columnar portion and including a material disposed in the first memory cell,
the plurality of second columnar portions includes:
an eighth columnar portion including an insulating material and connected to the fifth columnar portion in the first direction,
a ninth columnar portion disposed apart from the eighth columnar portion in the third direction, including an insulating material, and connected to the sixth columnar portion in the first direction, and
a tenth columnar portion disposed between the eighth columnar portion and the ninth columnar portion, including a material disposed in the second memory cell, and connected to the seventh columnar portion in the first direction,
the plurality of third columnar portions includes:
an eleventh columnar portion including an insulating material and being in contact with the fifth columnar portion,
a twelfth columnar portion disposed apart from the eleventh columnar portion in the third direction, including an insulating material, and being in contact with the sixth columnar portion, and
a thirteenth columnar portion disposed between the eleventh columnar portion and the twelfth columnar portion, including a material disposed in the first memory cell, and being in contact with the seventh columnar portion, and
the plurality of fourth columnar portions includes:
a fourteenth columnar portion including an insulating material and being in contact with the eighth columnar portion,
a fifteenth columnar portion disposed apart from the fourteenth columnar portion in the third direction, including an insulating material, and being in contact with the ninth columnar portion, and
a sixteenth columnar portion disposed between the fourteenth columnar portion and the fifteenth columnar portion, including a material disposed in the second memory cell, and being in contact with the tenth columnar portion.

3. The semiconductor storage device according to claim 2, wherein
the material disposed in the first memory cell and the material disposed in the second memory cell are an insulating material including silicon and oxygen, an insulating material including silicon and nitrogen, an insulating material including silicon, oxygen, and nitrogen, or polysilicon.

4. The semiconductor storage device according to claim 1, wherein
the first stacked body disposed under a portion where the first columnar portion and the third columnar portion are in contact with each other, has a length in the second direction that is shortened in a direction from the first stacked body toward the second stacked body in the first direction, and
the second stacked body disposed under a portion where the second columnar portion and the fourth columnar portion are in contact with each other, has a length in the second direction that is shortened in a direction from the first stacked body toward the second stacked body in the first direction.

5. The semiconductor storage device according to claim 1, wherein the plurality of first conductive layers and the plurality of second conductive layers include a tungsten material.

6. The semiconductor storage device according to claim 1, wherein the plurality of first insulating layers and the plurality of second insulating layers include oxygen and silicon.

7. The semiconductor storage device according to claim 1, wherein the plurality of first columnar portions and the plurality of second columnar portions include oxygen and silicon.

8. The semiconductor storage device according to claim 1, wherein the plurality of first memory pillars and the plurality of second memory pillars include oxygen, silicon and nitrogen.

9. The semiconductor storage device according to claim 1, wherein the plurality of first memory pillars and the plurality of second memory pillars include a tunnel insulating film.

10. The semiconductor storage device according to claim 1, further comprising:
a source line,
wherein the plurality of first memory pillars reach the upper surface of the source line.

11. The semiconductor storage device according to claim 10, further comprising:
a third insulating layer,
wherein the third insulating is between the first stacked body and the source line.

12. The semiconductor storage device according to claim 11, further comprising:
a substrate,
wherein the source line is between the first stacked body and the substrate.

13. The semiconductor storage device according to claim 12, further comprising:
a fourth insulating layer,
wherein the fourth insulating is between the substrate and the source line.

14. The semiconductor storage device according to claim 10, further comprising:
a bit line; and
a contact connected to the bit line and at least one of the plurality of second memory pillars.

15. The semiconductor storage device according to claim 14, further comprising:
a substrate.

16. The semiconductor storage device according to claim 15, wherein the bit line is between the substrate and at least one of the plurality of second memory pillars.
